(19) United States
(12) Patent Application Publication
(10) Pub. No.: US 2021/0111110 A1
(43) Pub. Date: Apr. 15, 2021

(54) SEMICONDUCTOR DEVICE PACKAGE

(71) Applicant: Advanced Semiconductor Engineering, Inc., Kaohsiung (TW)

(72) Inventor: Ting-Yang CHOU, Kaohsiung (TW)

(73) Assignee: Advanced Semiconductor Engineering, Inc., Kaohsiung (TW)

(21) Appl. No.: 16/597,740

(22) Filed: Oct. 9, 2019

(51) Int. Cl. H01L 23/498; H01L 23/31; H01L 23/538; H01L 25/10

(52) U.S. Cl. CPC H01L 23/49822; H01L 23/3128; H01L 23/5389; H01L 24/16; H01L 25/105; H01L 2224/16225; H01L 23/5386

(57) ABSTRACT

A semiconductor device package includes a semiconductor device in an encapsulating layer, an electrical conductor for electrical connection of the semiconductor device to an external device, and a redistribution structure for electrical connection between the semiconductor device and the electrical conductor. The redistribution structure includes dielectric layers stacked on each other in a direction extending between the encapsulating layer and the electrical conductor, wherein the dielectric layer most adjacent to the electrical conductor includes a first pattern under the electrical conductor, and circuit layers each corresponding to a respective one of the dielectric layers. The semiconductor device package further includes a conductive region disposed in the dielectric layer most adjacent to the electrical conductor according to the first pattern, and a first dielectric region, disposed in the dielectric layer most adjacent to the electrical conductor under the electrical conductor according to the first pattern, and surrounded by the conductive region.

### BACKGROUND

### 1. Field of the Disclosure

The present disclosure is generally related to semiconductor packaging and, in particular, to a semiconductor device package.

### 2. Description of the Related Art

Along with the rapid development in electronics industry and the progress of semiconductor processing technologies, semiconductor chips are integrated with an increasing number of electronic components to achieve improved electrical performance and additional functions. To ensure the desired performance and functions, electrical tests and/or reliability tests are performed for semiconductor chips during or after manufacturing. Such tests, however, may cause damage to a semiconductor package that includes the semiconductor chips.

### SUMMARY

Embodiments of the present disclosure provide a semiconductor device package that includes a semiconductor device in an encapsulating layer, an electrical conductor for electrical connection of the semiconductor device to an external device, and a redistribution structure for electrical connection between the semiconductor device and the electrical conductor. The redistribution structure includes dielectric layers stacked on each other in a direction extending between the encapsulating layer and the electrical conductor. At least one of the dielectric layers disposed adjacent to the electrical conductor has a larger size in the direction than at least one of the dielectric layers disposed adjacent to the encapsulating layer.

Some embodiments of the present disclosure provide a semiconductor device package that includes a semiconductor device in an encapsulating layer, an electrical conductor for electrical connection of the semiconductor device to an external device, and a redistribution structure for electrical connection between the semiconductor device and the electrical conductor. The redistribution structure includes dielectric layers stacked on each other in a direction extending between the encapsulating layer and the electrical conductor, wherein the dielectric layer most adjacent to the electrical conductor includes a pattern under the electrical conductor, and circuit layers each corresponding to a respective one of the dielectric layers. The semiconductor device package further includes conductive regions disposed in the dielectric layer most adjacent to the electrical conductor according to the pattern. The conductive regions electrically connect the circuit layer corresponding to the dielectric layer most adjacent to the electrical conductor and the circuit layer corresponding to the dielectric layer second most adjacent to the electrical conductor.

Embodiments of the present disclosure also provide a semiconductor device package that includes a semiconductor device in an encapsulating layer, an electrical conductor for electrical connection of the semiconductor device to an external device, and a redistribution structure for electrical connection between the semiconductor device and the electrical conductor. The redistribution structure includes dielectric layers stacked on each other in a direction extending between the encapsulating layer and the electrical conductor, wherein the dielectric layer most adjacent to the electrical conductor includes a first pattern under the electrical conductor, and circuit layers each corresponding to a respective one of the dielectric layers. The semiconductor device package further includes a conductive region disposed in the dielectric layer most adjacent to the electrical conductor according to the first pattern. The conductive region electrically connects the circuit layer corresponding to the dielectric layer most adjacent to the electrical conductor and the circuit layer corresponding to the dielectric layer second most adjacent to the electrical conductor. The semiconductor device package further includes a first dielectric region, disposed in the dielectric layer most adjacent to the electrical conductor under the electrical conductor according to the first pattern, and surrounded by the conductive region.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A is a cross-sectional view of a semiconductor device package in accordance with an embodiment of the present disclosure.

FIG. 1B is a cross-sectional view of a redistribution structure in the semiconductor device package illustrated in FIG. 1A, in accordance with an embodiment of the present disclosure.

FIG. 2A is a cross-sectional view showing a scenario of delamination that would occur in a redistribution structure.

FIG. 2B is a cross-sectional view showing another scenario of delamination that would occur in a redistribution structure.

FIG. 3A is a top view of a region, in a dielectric layer most adjacent to an electrical conductor, for holding the electrical conductor.

FIG. 3B is a top view of a pad region, in a circuit layer second most adjacent to the electrical conductor, for electrical connection to the electrical conductor.

FIG. 3C is a cross-sectional view of a redistribution structure in accordance with an embodiment of the present disclosure.

FIG. 4A is a top view of a region under an electrical conductor, in a dielectric layer most adjacent to the electrical conductor, including recess regions disposed according to a pattern, in accordance with an embodiment of the present disclosure.

FIG. 4B is a top view of a pad region, in a circuit layer second most adjacent to the electrical conductor, for electrical connection to the electrical conductor.

FIG. 4C is a cross-sectional view of a redistribution structure in accordance with another embodiment of the present disclosure.

FIG. 4D is a top view of a region under the electrical conductor, in a dielectric layer most adjacent to an electrical conductor, including recess regions disposed according to a pattern, in accordance with another embodiment of the present disclosure.

FIG. 4E is a top view of a region under the electrical conductor, in a dielectric layer most adjacent to an electrical conductor, including recess regions disposed according to a pattern, in accordance with yet another embodiment of the present disclosure.

FIG. 4F is a top view of a region under the electrical conductor, in a dielectric layer most adjacent to an electrical conductor, including recess regions disposed according to a pattern, in accordance with still another embodiment of the present disclosure.

FIG. 5A is a top view of a region under an electrical conductor, in a dielectric layer most adjacent to the electrical conductor, including a recess region disposed according to a first pattern, in accordance with an embodiment of the present disclosure.

FIG. 5B is a top view of a pad region for holding the electrical conductor, in a circuit layer second most adjacent to the electrical conductor, including a dielectric region disposed according to a second pattern, in accordance with an embodiment of the present disclosure.

FIG. 5C is a cross-sectional view of a redistribution structure in accordance with yet another embodiment of the present disclosure.

FIG. 6A, FIG. 6B, FIG. 6C, FIG. 6D, FIG. 6E, FIG. 6F, FIG. 6G, FIG. 6H, FIG. 6I, FIG. 6J, FIG. 6K, FIG. 6L, FIG. 6M, FIG. 6N, FIG. 6O, FIG. 6P, and FIG. 6Q are cross-sectional views each illustrating one or more stages of a method of manufacturing the semiconductor device package as described and illustrated with reference to FIG. 1A, in accordance with an embodiment of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

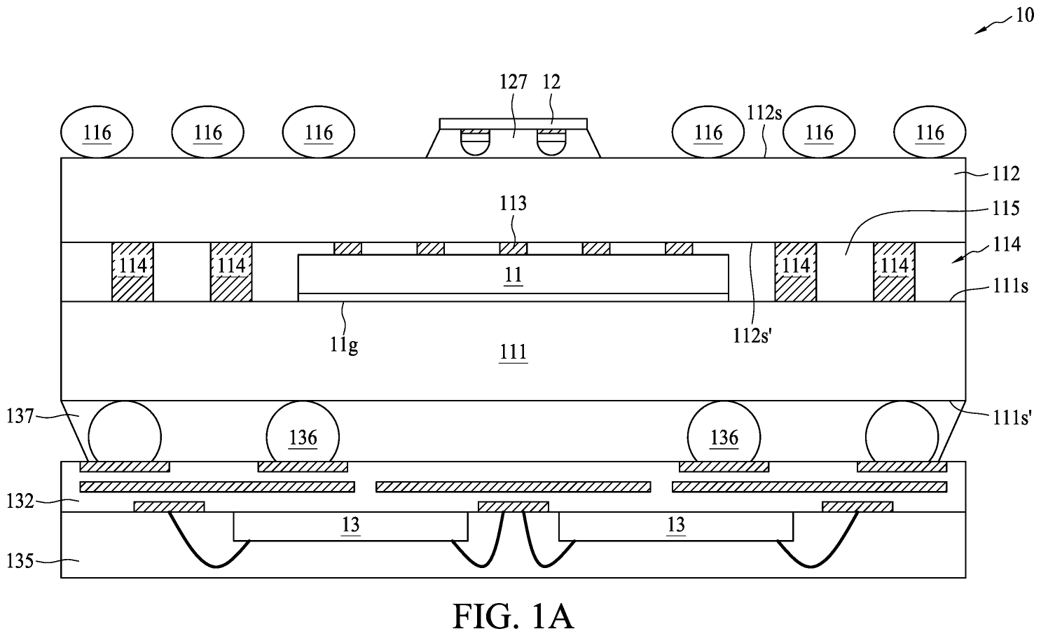

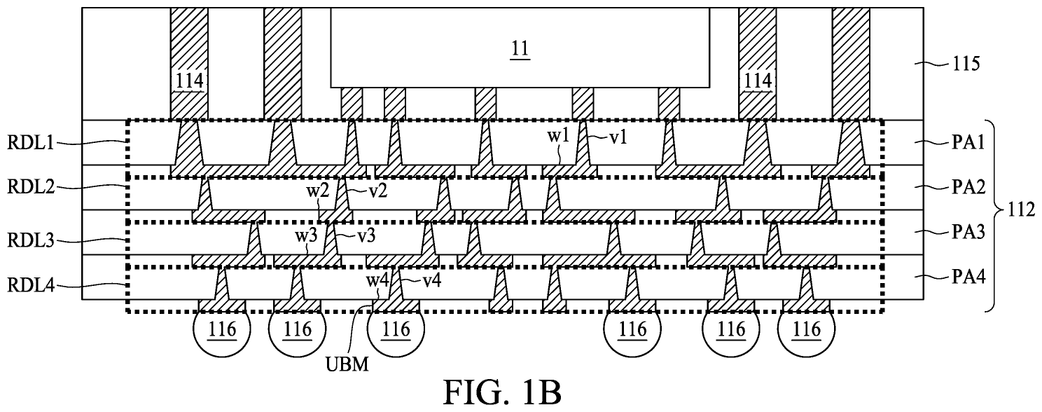

FIG. 1A is a cross-sectional view of a semiconductor device package 10 in accordance with an embodiment of the present disclosure.

Referring to FIG. 1A, the semiconductor device package 10 includes a first redistribution structure 111, a second redistribution structure 112, a first semiconductor device 11 disposed and electrically connected between the first redistribution structure 111 and the second redistribution structure 112, a second semiconductor device 12 disposed over the first semiconductor device 11 and electrically connected to the first semiconductor device 11 via the second redistribution structure 112, and one or more third semiconductor devices 13 disposed under the first semiconductor device 11 and electrically connected to the first semiconductor device 11 via the first redistribution structure 111. In an embodiment, the first semiconductor device 11 includes an application processor, the second semiconductor device 12 includes an integrated passive device, and the third semiconductor devices 13 include memory devices.

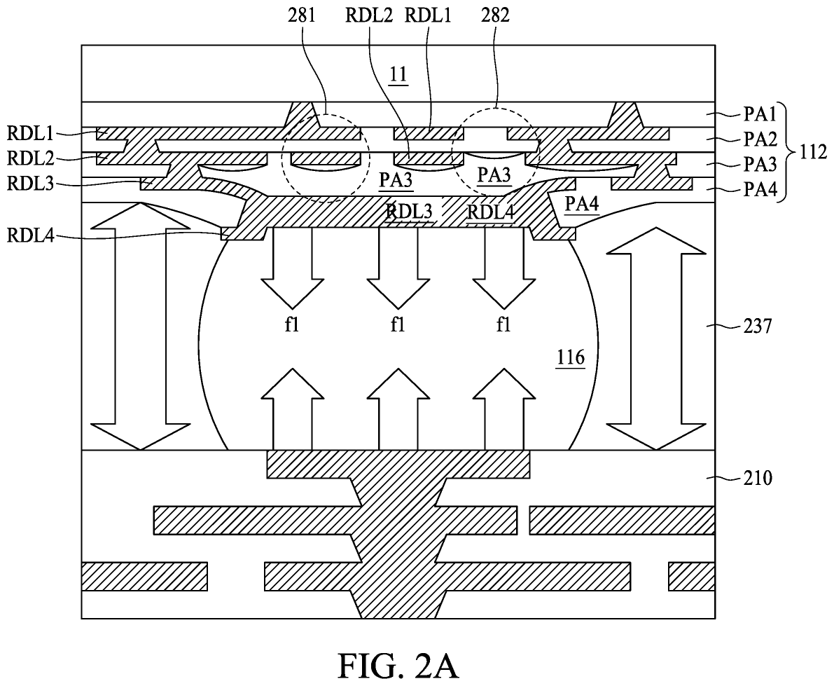

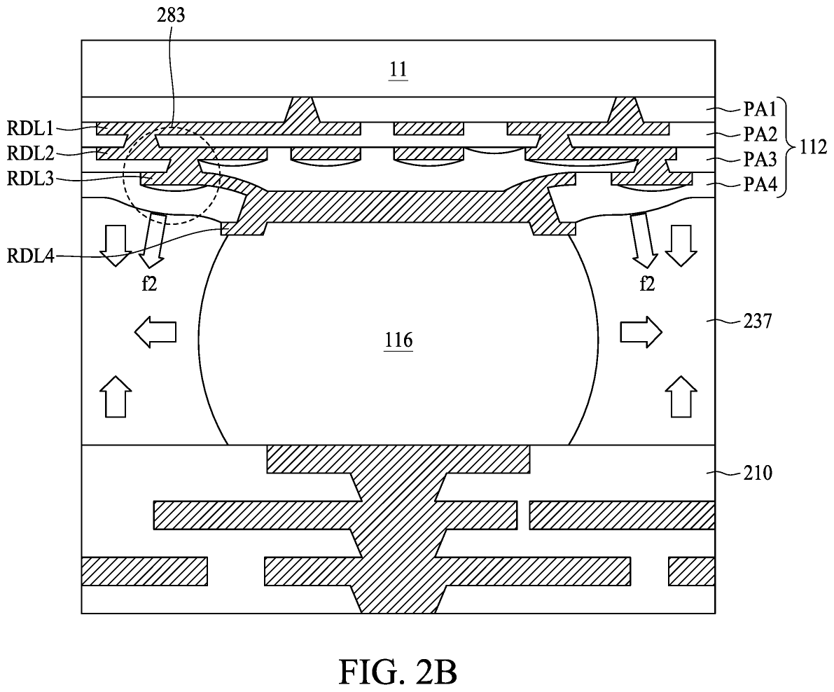

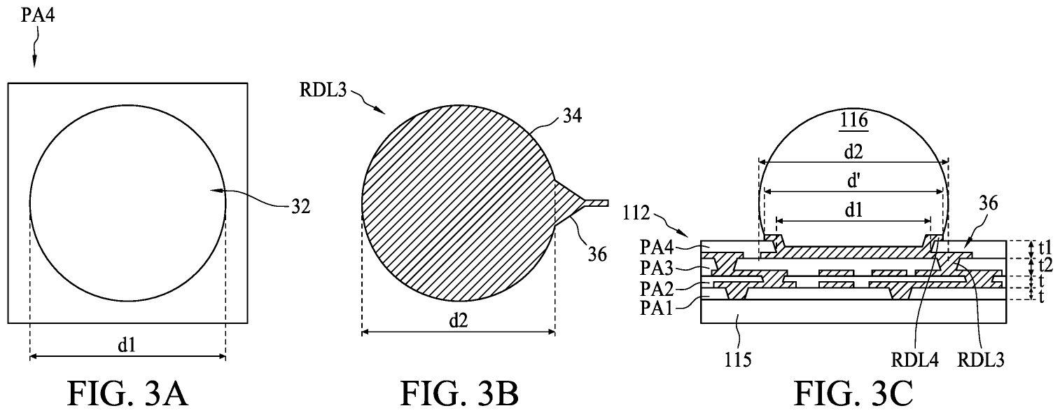

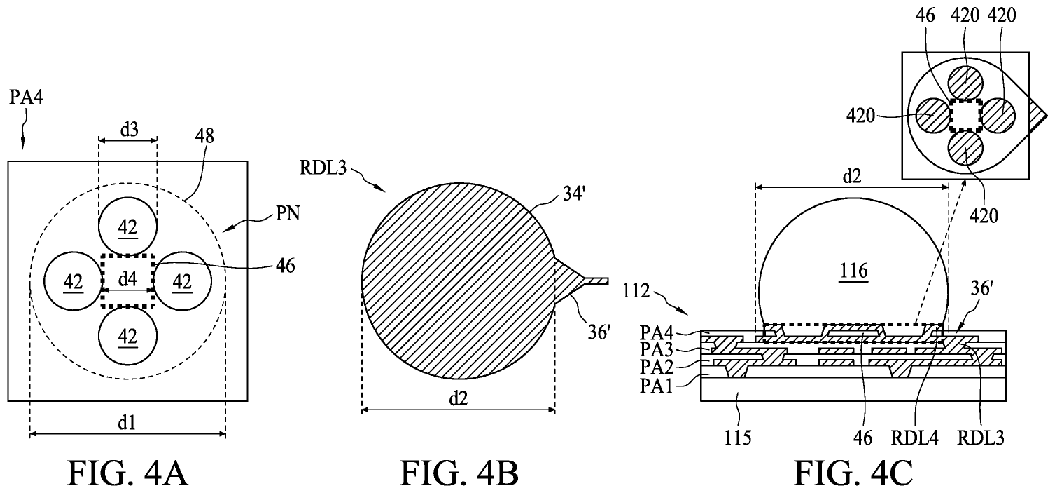

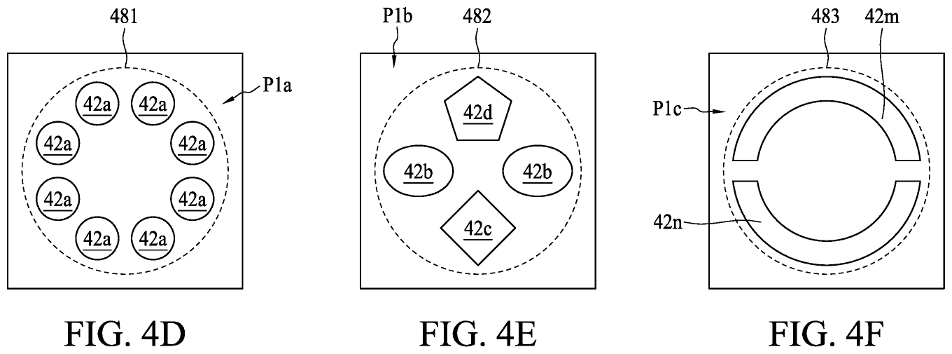

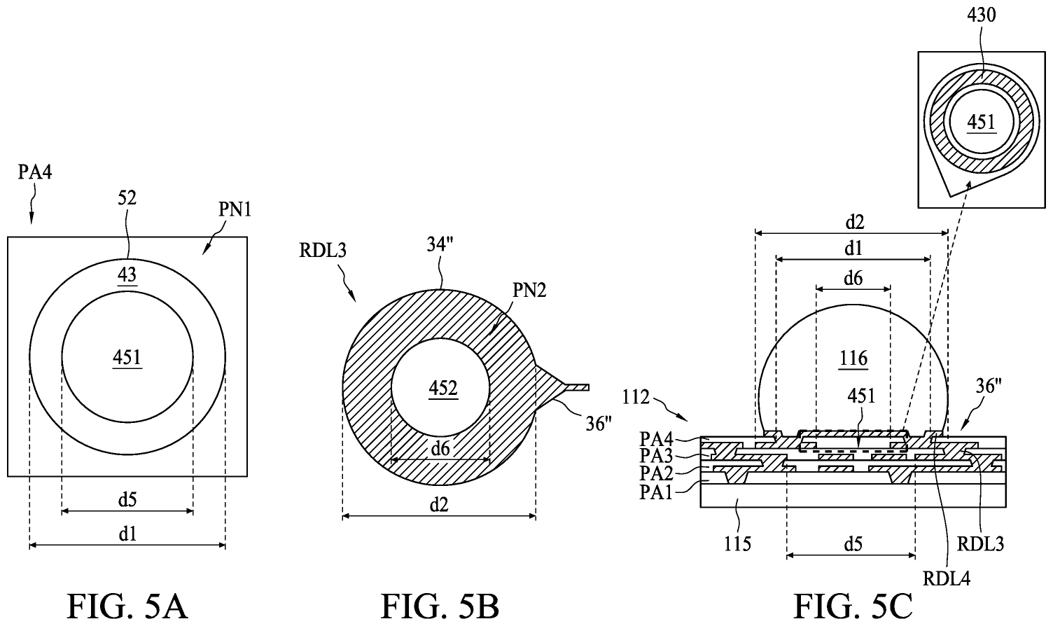

The first redistribution structure 111 has a first surface 111s and a second surface 111s′ opposite to the first surface 111s. The first redistribution structure 111 may include two dielectric layers and one circuit layers, thus forming a “2P1M” configuration. The second redistribution structure 112 has a first surface 112s and a second surface 112s′ opposite to the first surface 112s. In an embodiment, the second redistribution structure 112 includes four dielectric layers and four circuit layers, thus forming a “4P4M” configuration, which will be further discussed in detail with reference to FIG. 1B. The first redistribution structure 111 and the second redistribution structure 112 function to provide electrical interconnection among the first, second and third semiconductor devices 11, 12 and 13. Also, the second redistribution structure 112 functions to provide electrical connection between the first semiconductor device 11 and an external semiconductor device. According to an embodiment of the present disclosure, the second redistribution structure 112 includes a thicker dielectric layer (which will be discussed with reference to FIGS. 3A to 3C) to alleviate a delamination problem (which will be discussed with reference to FIGS. 2A and 2B). Moreover, according to another embodiment of the present disclosure, the second redistribution structure 112 includes a pattern in a dielectric layer (which will be discussed with reference to FIGS. 4A to 4C) to alleviate the delamination problem. Furthermore, according to yet another embodiment of the present disclosure, the second redistribution structure 112 includes a pattern in a dielectric layer and a corresponding pattern in a circuit layer (which will be discussed with reference to FIGS. 5A to 5C) to alleviate the delamination problem.

The first semiconductor device 11, disposed on the first surface 111s of the first redistribution structure 111, includes studs 113 exposed to and substantially flush with the second surface 112s′ of the second redistribution structure 112. An adhesive film 11g may be used to facilitate attaching the first semiconductor device 11 to the first redistribution structure 111. A patterned conductive layer 114, extending in an encapsulating layer 115 that encapsulates the first semiconductor device 11, is electrically connected between the first surface 111s of the first redistribution structure 111 and the second surface 112s′ of the second redistribution structure 112.

The second semiconductor device 12 is face-down connected to the first surface 112s of the second redistribution structure 112. An underfill 127 is applied between the second semiconductor device 12 and the second redistribution structure 112. The underfill 127 provides protection of the second semiconductor device 12 from moisture, ionic contaminants, radiation, and hostile operating environments with thermal, mechanical, shock, and vibration stresses. Electrical conductors 116, disposed on the first surface 112s of the second redistribution structure 112, provide electrical connection of the first semiconductor device 11 to an external semiconductor device.

The third semiconductor devices 13 are encapsulated in an encapsulating layer 135. The third semiconductor devices 13 is electrically connected to the first semiconductor device 11 via a redistribution structure 132 and electrical conductors 136 formed on the redistribution structure 132. The electrical conductors 136 are connected to the second surface 111s′ of the first redistribution structure 111, and are sealed in an underfill 137 disposed between the redistribution structure 132 and the first redistribution structure 111. The underfill 137 provides protection of the electrical conductors 136 from moisture, ionic contaminants, radiation, and hostile operating environments with thermal, mechanical, shock, and vibration stresses.

FIG. 1B is a cross-sectional view of the second redistribution structure 112 in the semiconductor device package 10 illustrated in FIG. 1A, in accordance with an embodiment of the present disclosure.

Referring to FIG. 1B, the second redistribution structure 112 includes dielectric layers PA1, PA2, PA3 and PA4 stacked on each other in a direction extending between the encapsulating layer 115 and the electrical conductors 116, and circuit layers RDL1, RDL2, RDL3 and RDL4 corresponding to the dielectric layers PA1, PA2, PA3 and PA4, respectively. Specifically, the first dielectric layer PA1 is disposed on the encapsulating layer 11, and is most adjacent to the encapsulating layer 115 or the first semiconductor device 11 among the dielectric layers PA1 to PA4. The second dielectric layer PA2 is disposed on the first dielectric layer PA1, and is second most adjacent to the encapsulating layer 115. The third dielectric layer PA3 is disposed on the second dielectric layer PA2, and is second most adjacent to the electrical conductors 116. The fourth dielectric layer PA4 is disposed on the third dielectric layer PA3, and is most adjacent to the electrical conductors 116.

The first circuit layer RDL1 includes a conductive via v1 extending in the first dielectric layer PA1 in the direction, and a wiring w1 or trace extending on a surface of the first dielectric layer PA1 from the conductive via v1. Similarly, the second circuit layer RDL2 includes a conductive via v2 extending in the second dielectric layer PA2 in the direction, and a wiring w2 extending on a surface of the second dielectric layer PA2 from the conductive via v2. In addition, the third circuit layer RDL3 includes a conductive via v3 extending in the third dielectric layer PA3 in the direction, and a wiring w3 extending on a surface of the third dielectric layer PA3 from the conductive via v3. The fourth circuit layer RDL4 includes a conductive via v4 extending in the fourth dielectric layer PA4 in the direction, and a pad such as a under bump metallization (UBM) pad electrically connected between the conductive via v4 and an electrical conductor 116. The UBM is used to improve adhesion of the electrical conductor 116.

The semiconductor device package 10 as described and illustrated with reference to FIGS. 1A and 1B may include a fan-out configuration. Advances in microelectronics technology have driven the demand for high-density semiconductor packaging as well as downsized semiconductor devices. Fan-out configuration, one of the latest trends in microelectronics packaging, allows multi-die packages. In such packages, however, delamination may occur and thus damage a semiconductor device package, as explained below with reference to FIGS. 2A and 2B.

FIG. 2A is a cross-sectional view showing a scenario of delamination that would occur in a redistribution structure 112.

Referring to FIG. 2A, an underfill 237 sealing an electrical conductor 116 is applied between the redistribution structure 112 and an external device 210. When a semiconductor device package including the redistribution structure 112 is put to a stress test such as a pressure cook test (PCT), temperature humidity test (THT), highly accelerated stress test (HAST) or unbiased HAST (uHAST), the underfill layer 237 is liable to hygroscopic swelling (double-headed arrows showing the movement) during the stress test. The swelling causes a force f1 to pull the electrical conductor 116 in the underfill layer 237 away from the redistribution structure 112. As a result, delamination occurs between dielectric layers in the redistribution structure 112 under the electrical conductor 116. For example, delamination occurs at an interface 282 between a second dielectric layer PA2 and a third dielectric layer PA3, given a P4M4 configuration. Also, delamination occurs between a dielectric layer and a circuit layer in the redistribution structure 112 under the electrical conductor 116. For example, delamination occurs at an interface 281 between a second circuit layer RDL2 and a third dielectric layer PA3 in a P4M4 configuration. Given the above, swelling of the underfill layer 237 during a stress test is likely to cause delamination in the redistribution structure 112 at regions under the electrical conductor 116. It may therefore be desirable to have a semiconductor device package that can solve or alleviate the delamination problems.

Furthermore, after the stress test, delamination may occur in the redistribution structure 112. FIG. 2B is a cross-sectional view showing another scenario of delamination that would occur in the redistribution structure 112.

Referring to FIG. 2B, when a heat source is removed after the stress test, the underfill layer 237 tends to shrink or deform (short wide arrows showing the movement). However, with the already delaminated regions 281 and 282 in the redistribution structure 112 under the electrical conductor 116, the redistribution structure 112 becomes more difficult to stretch as the underfill layer 237 shrinks. The shrinking of the underfill layer 237 after the stress test thus causes a force f2, at regions surrounding the region under the electrical conductor 116, to pull an uppermost dielectric layer away from a circuit layer beneath the uppermost dielectric layer. As a result, delamination occurs. For example, delamination occurs at an interface 283 between the fourth dielectric layer PA4 and the third circuit layer RDL3. Given the above, shrinking of the underfill layer 237 after a stress test is likely to cause delamination in the redistribution structure 112 at regions surrounding the region under the electrical conductor 116. Moreover, if delamination has occurred during the stress test, the shrinking may even cause the fourth dielectric layer PA4 to delaminate from the third circuit layer RDL3 or from the third dielectric layer PA3 or both all the way down along their interface. The delamination problems, which may adversely affect the reliability of a semiconductor device package, should be solved or alleviated.

FIG. 3A is a top view of a region 32, in a dielectric layer PA4 most adjacent to an electrical conductor 116, for holding the electrical conductor 116. Referring to FIG. 3A, the region 32 is a recess defined in the fourth dielectric layer PA4, and takes the form of a circle having a first diameter d1. During a manufacturing process, the recess defined in the fourth dielectric layer PA4 in an operation is occupied or filled by a conductive material in a subsequent operation for forming the fourth circuit layer RDL4, which includes forming a UBM over the recess. The UBM corresponding to the regions 32 takes the form of a circle having a diameter d′. In an embodiment, the diameter d′ of a UBM is approximately 250 micrometers (μm), and the first diameter d1 of the region 32 is substantially 210 micrometers (μm).

FIG. 3B is a top view of a pad region 34, in a circuit layer RDL 3 second most adjacent to the electrical conductor 116, for electrical connection to the electrical conductor 116. Referring to FIG. 3B, the pad region 34 takes the form of a circle having a second diameter d2. The second diameter d2 is greater than the first diameter d1 to ensure smooth electrical connection between the electrical conductor 116 and the third circuit layer RDL3. In an embodiment, the second diameter d2 is substantially 270 micrometers (μm). The third circuit layer RDL3 includes a conductive portion 36 connected to the pad region 34 and extending therefrom.

FIG. 3C is a cross-sectional view of a redistribution structure 112 in accordance with an embodiment of the present disclosure. Referring to FIG. 3C, in the direction the dielectric layers PA1 to PA4 are stacked, the fourth dielectric layer PA4 (e.g., the dielectric layer most adjacent to the electrical conductor 116) has a thickness t1, the third dielectric layer PA3 (e.g., the dielectric layer second most adjacent to the electrical conductor 116) has a thickness t2, and the second dielectric layer PA2 (e.g., the dielectric layer second most adjacent to the first encapsulating layer 115) and the first dielectric layer PA1 (e.g., the dielectric layer most adjacent to the first encapsulating layer 115) have a thickness t. In an embodiment, at least one of the dielectric layers PA4 or PA3 disposed adjacent to the electrical conductor 116 has a larger size in the direction than at least one of the dielectric layers PA2 or PA1 disposed adjacent to the encapsulating layer 115. Accordingly, the thickness t4 or t3 or both is greater than the thickness t. A thicker dielectric layer PA4 or PA3 or both is believed to provide more “buffer” in response to the swelling or shrinking of an underfill and thus is more likely to prevent delamination in the redistribution structure 112. In another embodiment, the fourth dielectric layer PA4 has a larger size in the direction than the third dielectric layer PA3. Accordingly, the thickness t4 is greater than the thickness t3. In still another embodiment, the fourth dielectric layer PA4 has a same size in the direction as the third dielectric layer PA3. Accordingly, the thickness t4 equals the thickness t3. In an embodiment according to the present disclosure, the thickness t4, t3 and t are approximately 14, 12 and 10 μm, respectively.

The buffering effect of the thicker dielectric layer PA4 or PA3 helps alleviate the delamination problems. Specifically, during a stress test which may cause swelling of an underfill layer associated with the electrical conductor 116, the delamination problems that would occur between the third dielectric layer PA3 and the second circuit layer RDL2 or between the third dielectric layer PA3 and the second dielectric layer PA2 in the redistribution structure 112 at regions under the electrical conductor 116, as described and illustrated with reference to FIG. 2A, can be alleviated or prevented. Furthermore, after a stress test which may cause shrinking of the underfill layer associated with the electrical conductor 116, the delamination problems that would occur between the fourth dielectric layer PA4 and the third circuit layer RDL3 in the redistribution structure 112 at regions surrounding the region under the electrical conductor 116, where the conductive portion 36 may be located, as described and illustrated with reference to FIG. 2B, can be alleviated or prevented.

FIG. 4A is a top view of a region 48 under an electrical conductor 116, in a dielectric layer PA4 most adjacent to the electrical conductor 116, including recess regions 42 disposed according to a pattern PN, in accordance with an embodiment of the present disclosure.

Referring to FIG. 4A, the recess regions 42 in the region 48 may each take the form of a circle, and are arranged according to the pattern PN to define a dielectric region 46, which is substantially surrounded by the recess regions 42. In addition, the recess regions 42 may be symmetrically arranged with respect to the dielectric region 46. The region 48 for holding the electrical conductor 116 has a diameter d1, each recess region 42 has a diameter d3, and the dielectric region 46 amidst the recess regions 42 has a width d4. Dimensions of the recess regions 42 and the dielectric region 46 may be predetermined to ensure that, when the recess regions 42 are filled with a conductive material in a manufacturing process and become conductive regions, the conductive regions provide enough electrical conductivity for the corresponding electrical conductor 116 while the dielectric region 46 provides buffering effect to prevent delamination. In an embodiment, the diameter d1 is substantially 210 μm, the diameter d3 is substantially 75 μm, and the width d4 is substantially 50 μm.

The buffering effect of the dielectric region 46 helps alleviate the delamination problems. Specifically, during a stress test which may cause swelling of an underfill layer associated with the electrical conductor 116, the delamination problems that would occur between the third dielectric layer PA3 and the second circuit layer RDL2 or between the third dielectric layer PA3 and the second dielectric layer PA2 in the redistribution structure 112 at regions under the electrical conductor 116, as described and illustrated with reference to FIG. 2A, can be alleviated or prevented. Furthermore, after a stress test which may cause shrinking of the underfill layer associated with the electrical conductor 116, the delamination problems that would occur between the fourth dielectric layer PA4 and the third circuit layer RDL3 in the redistribution structure 112 at regions surrounding the region under the electrical conductor 116, where the conductive portion 36′ may be located, as described and illustrated with reference to FIG. 2B, can be alleviated or prevented.

FIG. 4B is a top view of a pad region 34′, in the circuit layer RDL3 second most adjacent to the electrical conductor 116, for electrical connection to the electrical conductor 116. The pad region 34′ is the same as or similar to the pad region 34 described and illustrated with reference to FIG. 3B, and has a diameter d2. The third circuit layer RDL3 includes a conductive portion 36′ connected to the pad region 34′ and extending therefrom. The conductive portion 36′ is similar to the conductive portion 36 described and illustrated with reference to FIG. 3B.

FIG. 4C is a cross-sectional view of a redistribution structure 112 in accordance with another embodiment of the present disclosure.

Referring to FIG. 4C, the dielectric region 46 with the fourth dielectric layer PA4 enhances the adhering between the third dielectric layer PA3 and the fourth dielectric layer PA4, so the delamination problems can be alleviated or prevented. Referring back to FIG. 2A, the third circuit layer RDL3 and the fourth circuit layer RDL4 at portions under the electrical conductor 116 are caused by the force f1 to contact each other, resulting in the delamination between the second dielectric layer PA2 and the third dielectric layer PA3, and between the second circuit layer RDL2 and the third dielectric layer PA3. In the present embodiments of FIGS. 4A to 4C, a contact area between the third circuit layer RDL3 and the fourth circuit layer RDL4 at portions under the electrical conductor 116 is reduced, which helps alleviate the delamination problem. For example, the contact area is reduced to the areas of the recess regions 42. In addition, the fourth dielectric layer PA4 at a portion under the electrical conductor 116, e.g., the dielectric region 46, facilitates the buffering effect, which also helps alleviate the delamination problem.

FIG. 4D is a top view of a region 481 under an electrical conductor 116, in a dielectric layer PA4 most adjacent to the electrical conductor 116, including recess regions 42a disposed according to a pattern p1a, in accordance with another embodiment of the present disclosure. Referring to FIG. 4D, the recess regions 42a are arranged along the peripheral of the region 481. The number of the recess regions 42a is eight but not limited thereto. Consequently, the number of conductive regions (not shown) resulting from the recess regions 42a is eight. In addition, the recess regions 42a may be arranged symmetrically with respect to, for example, the center point or the diameter of the region 481. Similarly, the conductive regions resulting from the recess regions 42a may be symmetrically arranged.

FIG. 4E is a top view of a region 482 under an electrical conductor 116, in a dielectric layer PA4 most adjacent to the electrical conductor 116, including recess regions 42b, 42c and 42d disposed according to a pattern p1b, in accordance with yet another embodiment of the present disclosure. Referring to FIG. 4E, the recess regions 42b have an oval shape, the recess region 42c has a diamond shape, and the recess region 42d has a pentagon shape. Consequently, conductive regions (not shown) resulting from the recess regions 42b, 42c and 42d have an oval, diamond and pentagon shape, respectively.

FIG. 4F is a top view of a region 483 under an electrical conductor 116, in a dielectric layer PA4 most adjacent to the electrical conductor 116, including recess regions 42m and 42n disposed according to a pattern plc, in accordance with still another embodiment of the present disclosure. Referring to FIG. 4F, the recess regions 42m and 42n have an arc shape extending along an upper peripheral and a lower peripheral, respectively, of the region 483. Consequently, conductive regions (not shown) resulting from the recess regions 42m and 42n have an arc shape. In addition, the recess regions 42m and 42n may be arranged symmetrically with respect to, for example, the center point or the diameter of the region 483. Similarly, the conductive regions resulting from the recess regions 42m and 42n may be symmetrically arranged.

FIG. 5A is a top view of a region 52 under an electrical conductor 116, in a dielectric layer PA4 most adjacent to the electrical conductor 116, including a recess region 43 disposed according to a first pattern PN1, in accordance with an embodiment of the present disclosure.

Referring to FIG. 5A, the recess region 43 takes the form of a ring shape, and surrounds a first dielectric region 451 in the fourth dielectric layer PA4. In other embodiments, the recess region 43 may have an oval shape or a polygonal shape. The recess region 43 has an outer diameter d1 and an inner diameter d5. In an embodiment, the outer diameter d1 is approximately 210 μm and the inner diameter d5 is approximately 140 μm.

FIG. 5B is a top view of a pad region 34″ for electrical connection to an electrical conductor 116, in a circuit layer RDL3 second most adjacent to the electrical conductor 116, including a dielectric region 452 disposed according to a second pattern PN2, in accordance with an embodiment of the present disclosure.

Referring to FIG. 5B, the second pattern PN2 corresponds to the first pattern PN1 in shape, and defines the dielectric region 452 with a smaller diameter d6 than the diameter d5. In an embodiment, the diameter d6 is approximately 120 μm. As such, since d2 and d5 are larger than d1 and d6, respectively, the pad region 34″ in the third circuit layer RDL3 has a larger dimension (d2-d6) than the recess region 43 having a dimension (d1-d5). Consequently, when a conductive material fills in the recess region 43 in forming the fourth circuit layer RDL4 during a manufacturing process, a conductive region resulting from the recess region 43 may be fully covered by the third circuit layer RDL3 in the pad region 34″, which ensures the electrical connection between the third circuit layer RDL3 and the fourth circuit layer RDL4.

The third circuit layer RDL3 includes a conductive portion 36″ connected to the pad region 34″ and extending therefrom. The conductive portion 36″ is similar to the conductive portion 36 described and illustrated with reference to FIG. 3B.

FIG. 5C is a cross-sectional view of a redistribution structure 112 in accordance with yet another embodiment of the present disclosure.

Referring to FIG. 5C, in particular to an amplified portion, the dielectric region 451 with the fourth electric layer PA4 enhances the adhering between the third electric layer PA3 and the fourth dielectric layer PA4, so the delamination problems can be alleviated or prevented. Specifically, due to the dielectric region 451, a contact area between the third circuit layer RDL3 and the fourth circuit layer RDL4 is reduced, while a contact area between the third dielectric layer PA3 and the fourth dielectric layer PA4 is increased. As a result, during a stress test which may cause swelling of an underfill layer associated with the electrical conductor 116, the delamination problems that would occur between the third dielectric layer PA3 and the second circuit layer RDL2 or between the third dielectric layer PA3 and the second dielectric layer PA2 in the redistribution structure 112 at regions under the electrical conductor 116, as described and illustrated with reference to FIG. 2A, can be alleviated or prevented. Furthermore, after a stress test which may cause shrinking of the underfill layer associated with the electrical conductor 116, the delamination problems that would occur between the fourth dielectric layer PA4 and the third circuit layer RDL3 in the redistribution structure 112 at regions surrounding the region under the electrical conductor 116, where the conductive portion 36″ may be located, as described and illustrated with reference to FIG. 2B, can be alleviated or prevented.

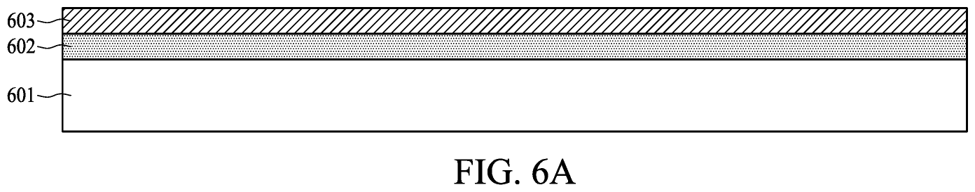

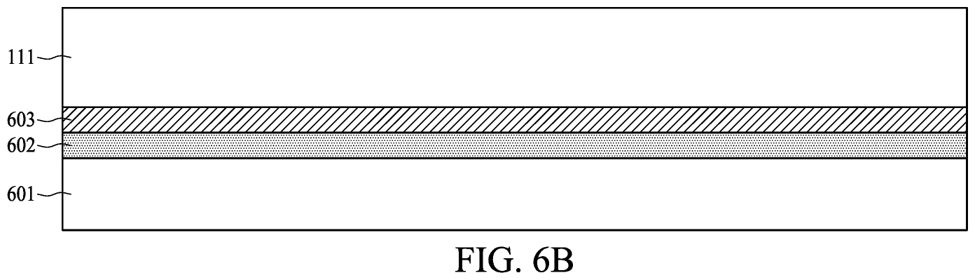

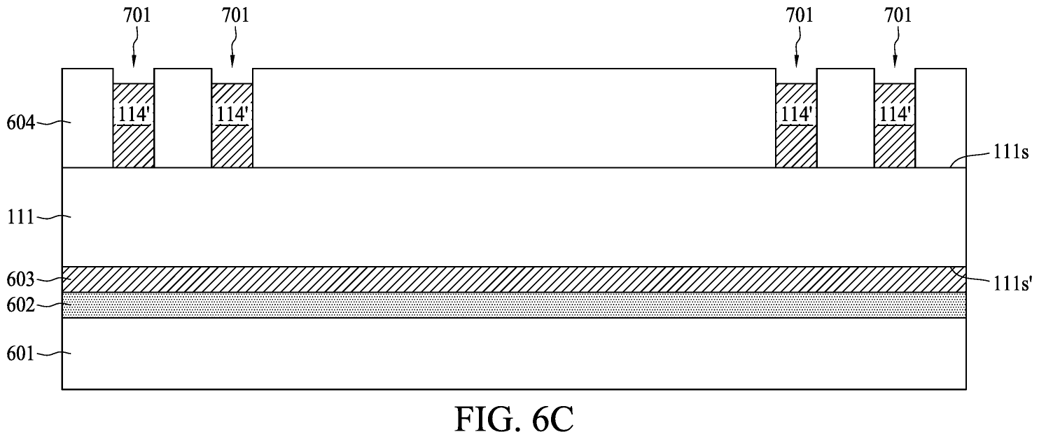

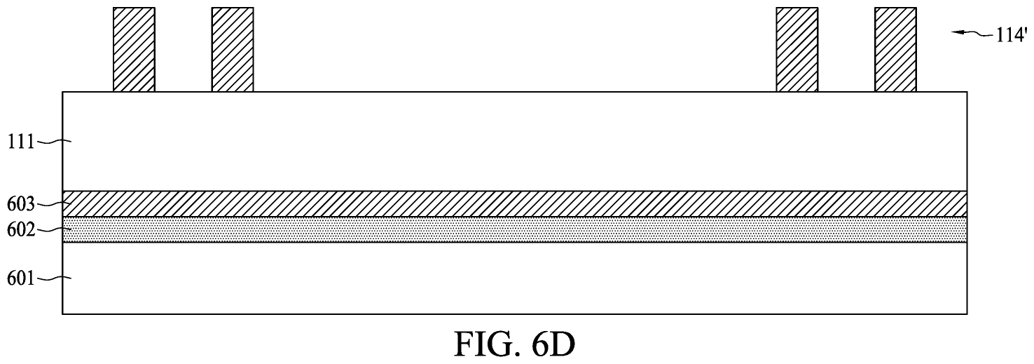

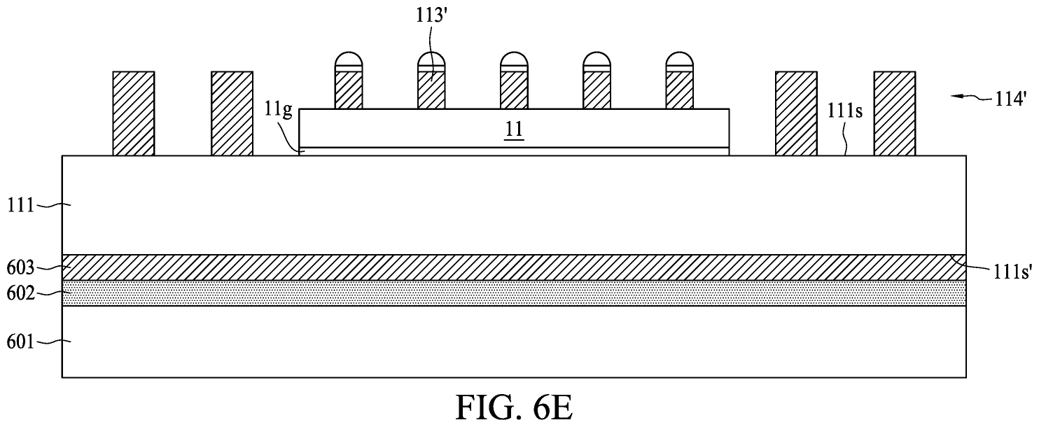

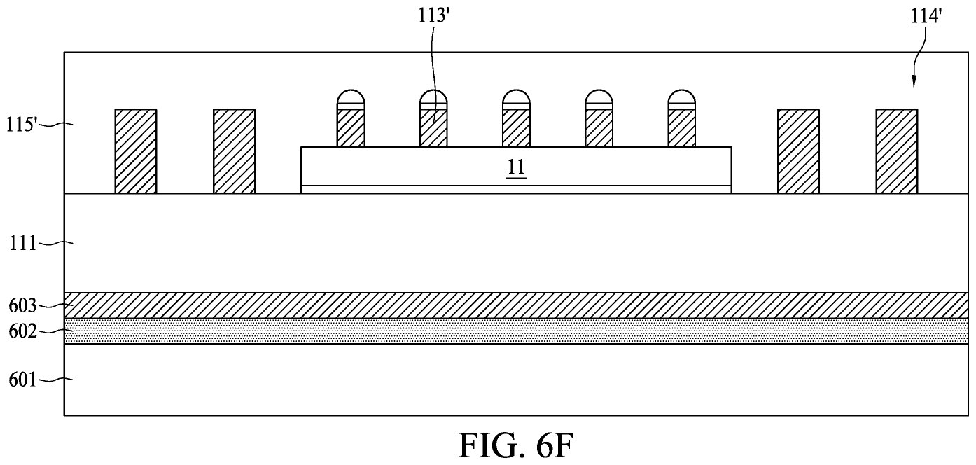

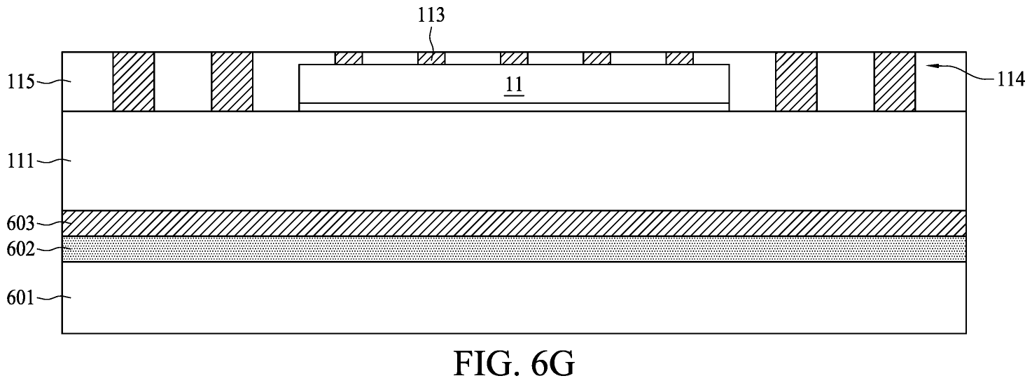

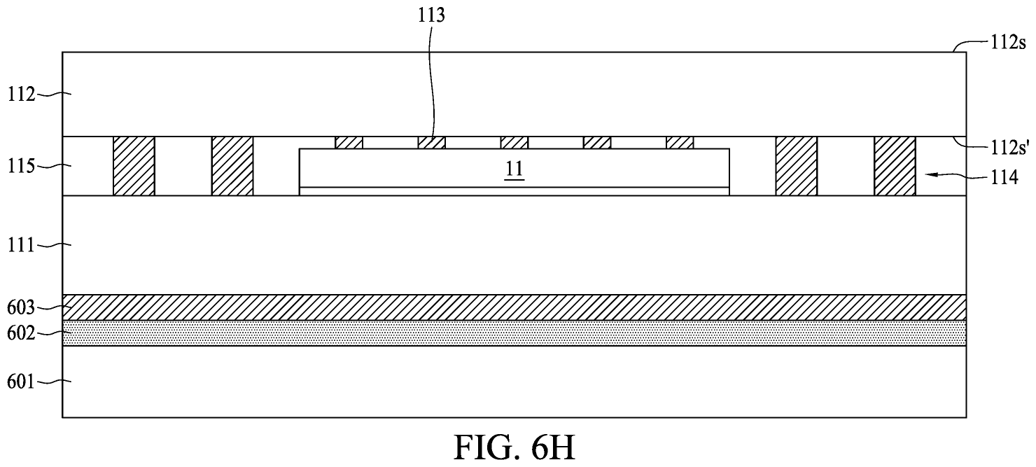

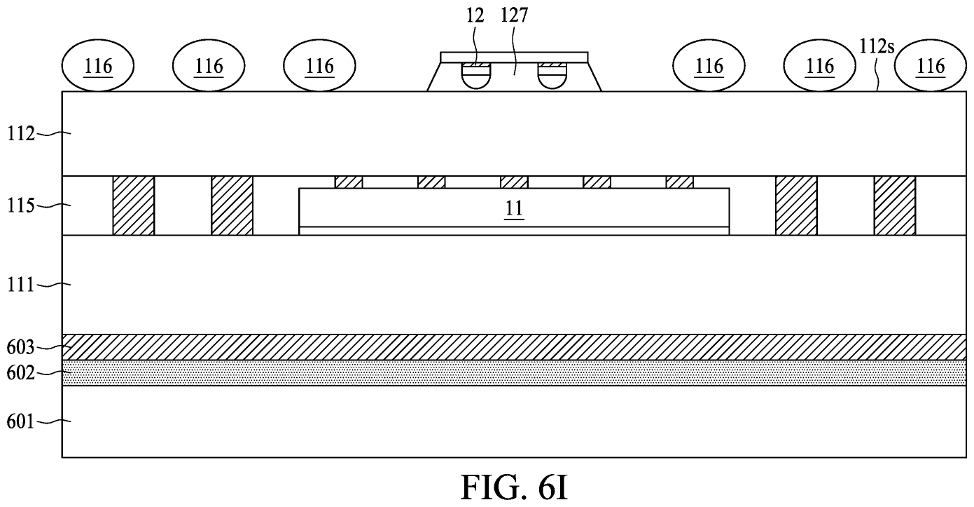

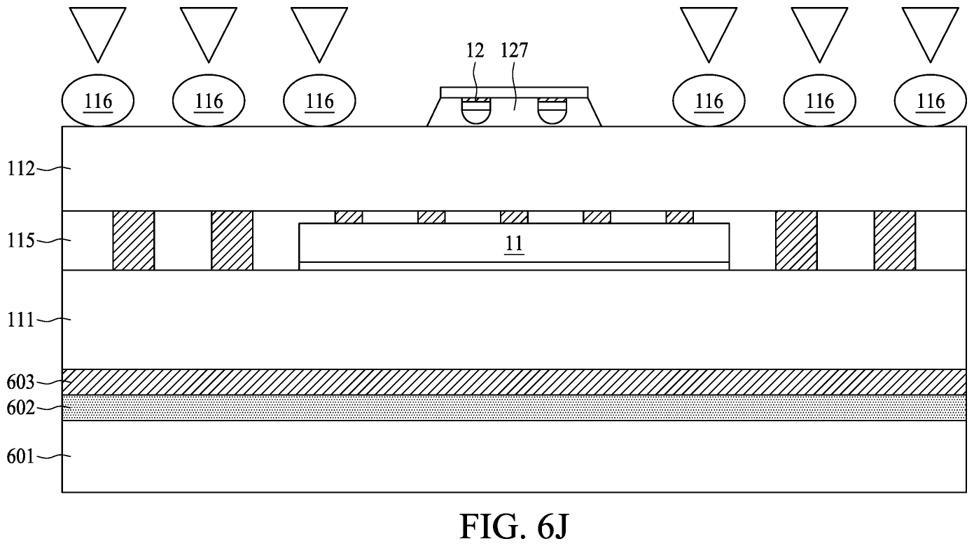

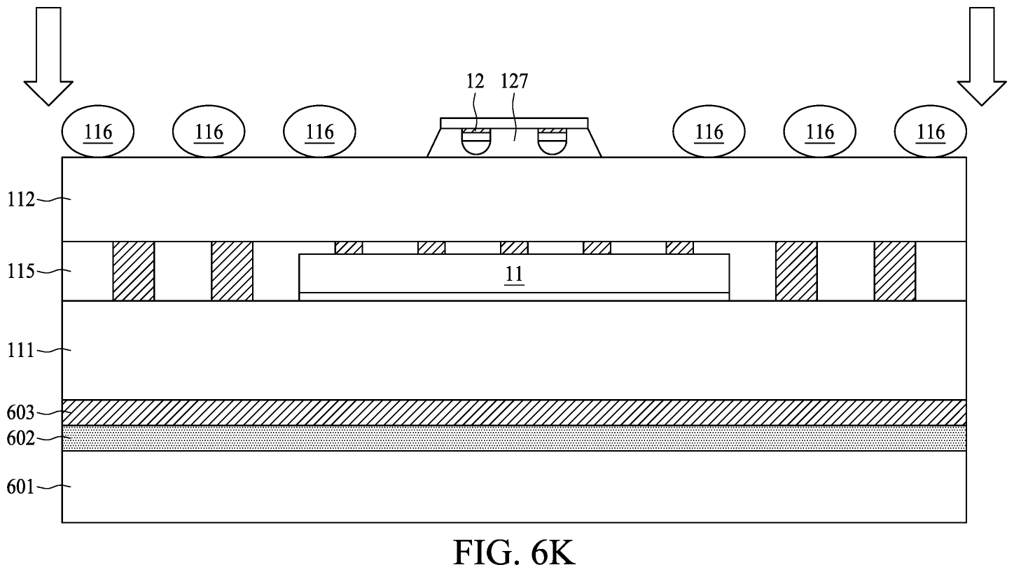

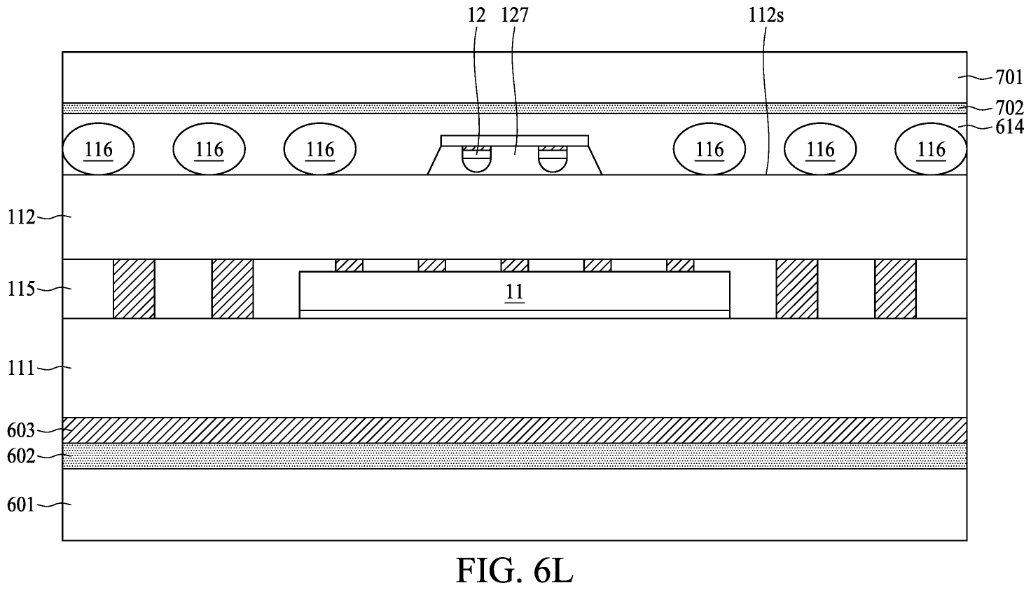

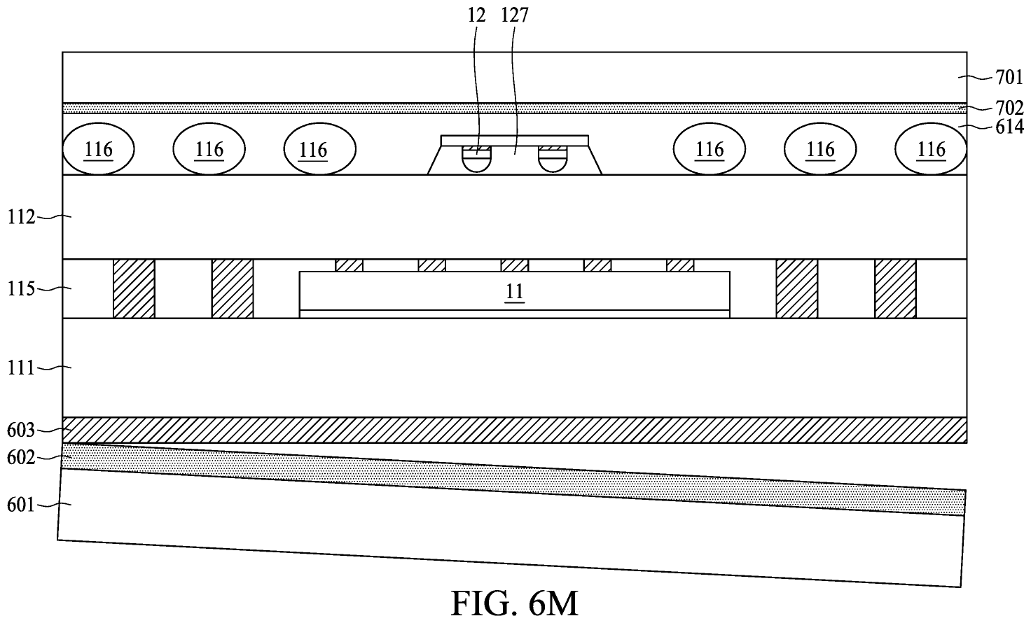

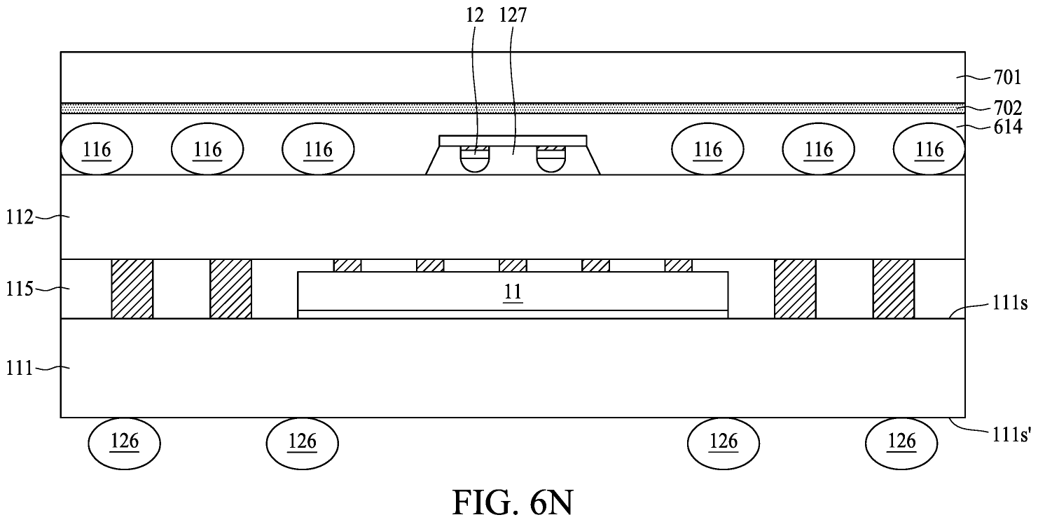

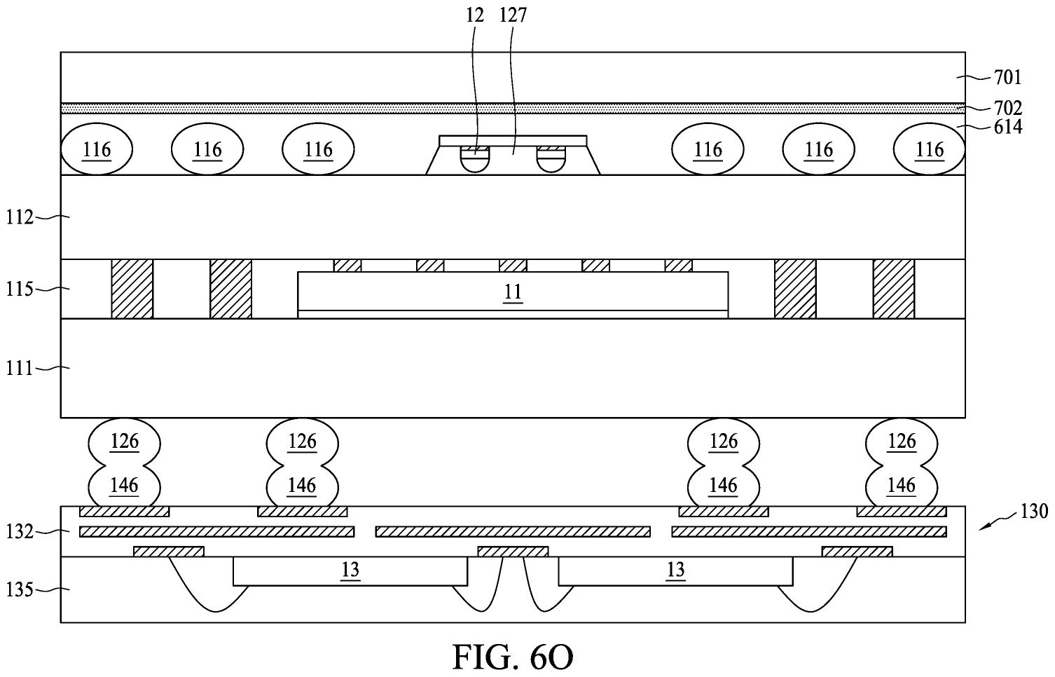

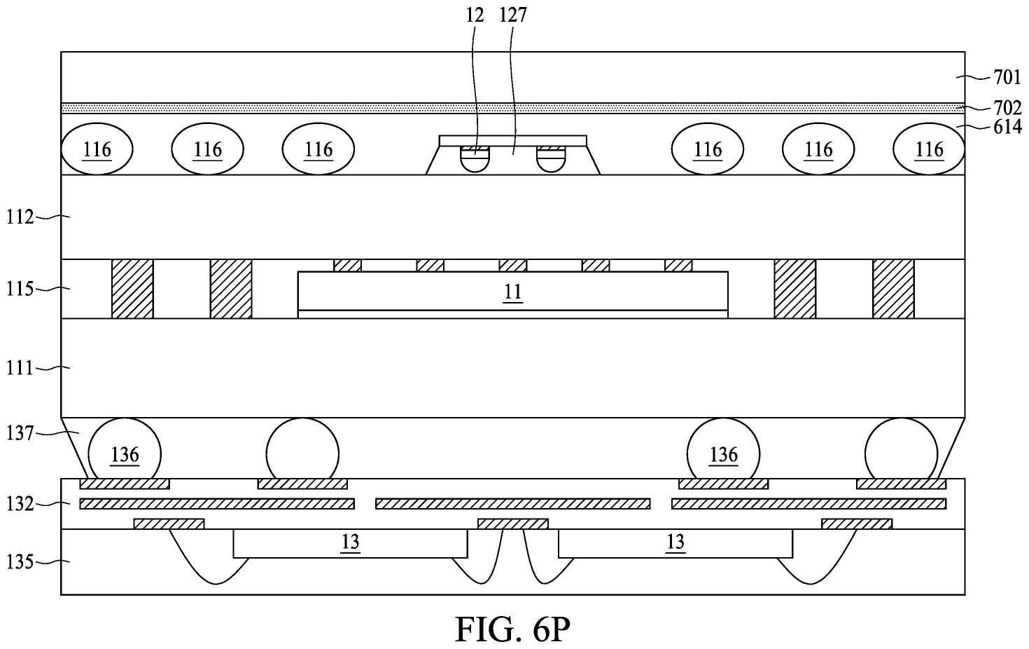

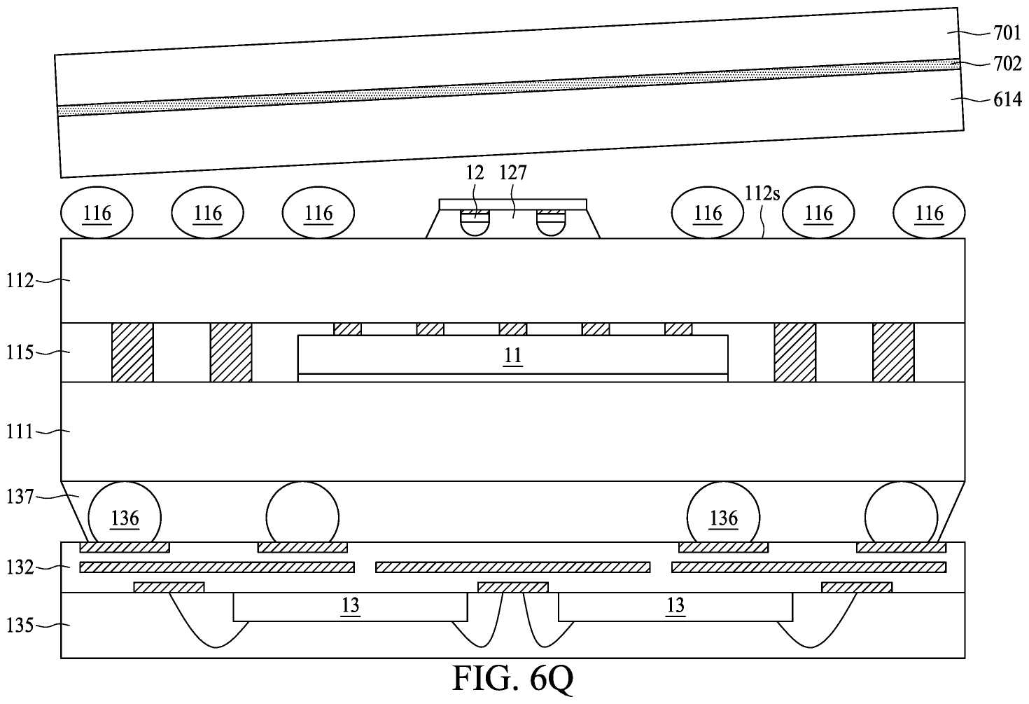

FIG. 6A through FIG. 6Q are cross-sectional views each illustrating one or more stages of a method of manufacturing the semiconductor device package as described and illustrated with reference to FIG. 1A, in accordance with an embodiment of the present disclosure.

Referring to FIG. 6A, a carrier 601 with a release film 602 is provided. The carrier 601 functions to support semiconductor components, devices or structures to be subsequently formed or disposed thereon. In an embodiment, the carrier 601 includes a glass carrier having a thickness of approximately 800 micrometers (μm). The release film 602 functions to facilitate release of the carrier 601 from a semiconductor structure temporarily held by the carrier 601. In an embodiment, the release film 602 includes polymer and has a thickness of approximately 0.5 μm.

Next, a buffer layer 603 is formed on the release film 602 by, for example, a coating process. The buffer layer 603 serves as a seed layer. The buffer layer 603 may include titanium (Ti), a titanium-tungsten alloy (TiW), nickel (Ni), copper (Cu), a titanium-copper alloy (TiCu), silver (Ag), gold (Au), or other suitable conductive materials. In an embodiment, the buffer layer 603 has a thickness of approximately 0.3 μm.

Referring to FIG. 6B, a first redistribution structure 111 is formed on the buffer layer 603. The first redistribution structure 111 functions to provide interconnection and may include dielectric layers and circuit layers. In an embodiment, the first redistribution structure 111 includes two dielectric layers and one circuit layer or a “2P1M” structure. The first redistribution structure 111 has a first surface 111s and a second surface 111s′ opposite to the first surface 111s.

Referring to FIG. 6C, a patterned conductive layer 114′ is formed on the first surface 111s of the first redistribution structure 111. An exemplary process of forming the patterned conductive layer 114′ includes forming a patterned dry film 604 on the first surface 111s of the first redistribution structure 111, exposing portions of the first redistribution structure 111 through openings 701, and disposing a conductive material onto the first surface 111s at the exposed portions by plating. In an embodiment, the patterned dry film 604 includes an acrylic film having a thickness of approximately 240 μm. In addition, the patterned conductive layer 114′ includes copper and has a thickness between approximately 170 μm and 240 μm. After the patterned conductive layer 114′ is formed, the patterned dry film 604 is removed, resulting in the patterned conductive layer 114′ as illustrated in FIG. 6D.

Referring to FIG. 6E, a first semiconductor device 11 with conductive studs 113′ is disposed on the first surface 111s of the first redistribution structure 111 by a pick-and-place process. The first semiconductor device 11 includes an application processor. An adhesive film 11g may be used to facilitate attaching the first semiconductor device 11 to the first redistribution structure 111.

Referring to FIG. 6F, an encapsulating layer 115′ is formed on the first redistribution structure 111, covering the patterned conductive layer 114′, the first semiconductor device 11 and the conductive studs 113′. The encapsulating layer 115′ may include a molding compound.

Referring to FIG. 6G, the encapsulating layer 115′ is then reduced in height by, for example, a grinding process such as a mechanical polishing process, resulting in a reduced encapsulating layer 115. The grinding process also reduces the patterned conductive layer 114′ and the conductive studs 113′ in height, resulting in a patterned conductive layer 114 and conductive studs 113, respectively. The patterned conductive layer 114 functions to provide interconnection for the first semiconductor device 11. In an embodiment, the patterned conductive layer 114 has a thickness of approximately 170 μm. Moreover, the conductive studs 113 serve as input/output (I/O) pads of the first semiconductor device 11, and have a thickness of approximately 25 μm.

Subsequently, after the encapsulating layer 115′ is reduced, a second redistribution structure 112 is formed on the reduced encapsulating layer 115, as illustrated in FIG. 6H. The second redistribution structure 112 is the same as or similar to that described and illustrated with reference to FIG. 1B and thus is not further discussed. The second redistribution structure 112 includes a first surface 112s, on which electrical connectors 116 for external connection will be formed, and a second surface 112s′, on the encapsulating layer 115, opposite to the first surface 112. According to an embodiment as described and illustrated with reference to FIGS. 3A through 3C, in the second redistribution structure 112, a dielectric layer disposed adjacent to the first surface 112s is thicker than one disposed adjacent to the second surface 112s′. Moreover, according to an embodiment as described and illustrated with reference to FIGS. 4A through 4C, the dielectric layer most adjacent to the first surface 112s includes under the electrical conductor conductive regions arranged according to a pattern. The conductive regions provide enough electrical conductivity for the corresponding electrical conductor 116, while a dielectric region substantially defined between or amidst the conductive regions provides buffering effect to prevent delamination. Furthermore, according to an embodiment as described and illustrated with reference to FIGS. 5A through 5C, the dielectric layer most adjacent to the first surface 112s includes under the electrical conductor a conductive region arranged according to a first pattern. The conductive region surrounds a first dielectric layer in the most adjacent dielectric layer. Also, the circuit layer second most adjacent to the first surface 112s includes a second dielectric region disposed according to a second pattern corresponding to the first pattern. The conductive region provides enough electrical conductivity for the corresponding electrical conductor 116. The first and second dielectric regions are connected to each other and thus may provide more buffering to prevent delamination than a single dielectric layer.

Referring to FIG. 6I, electrical conductors 116 are mounted on a surface 112s of the second redistribution structure 112 over the reduced encapsulating layer 115. In addition, a second semiconductor device 12 is mounted on the surface 112s of the second redistribution structure 112. The electrical conductors 116 provide electric connection between the first semiconductor device 11 and an external semiconductor device or component (not shown). The electrical connectors 116 may include solder balls, which may be arranged in a ball grid array “BGA”. The electrical connectors 116 may include controlled collapse chip connection (C4) bumps, including lead based or lead-free bumps or balls. The second semiconductor device 12 includes an integrated passive device, which in turn may include a resistor, a capacitor, an inductor or a combination thereof. In the present embodiment, the second semiconductor device 12 is die-down attached onto the surface 112s of the second redistribution structure 112. An underfill 127 is applied between the second semiconductor device 12 and the second redistribution structure 112. The underfill 127 provides protection of the second semiconductor device 12 from moisture, ionic contaminants, radiation, and hostile operating environments with thermal, mechanical, shock, and vibration stresses.

Referring to FIG. 6J, a wafer level function test (represented by triangles) is performed to determine if electric performance of semiconductor structures of a wafer manufactured so far on the carrier 601 is desirable. If affirmative, then in FIG. 6K, edges of the wafer are trimmed (indicated by arrows showing movement) to remove excessive encapsulating material to facilitate a subsequent bonding process.

Referring to FIG. 6L, an adhesive layer 614 is formed on the surface 112s of the second redistribution structure 112, covering the second semiconductor device 12 and the electrical conductors 116. Next, another carrier 701 with a release film 702 is bonded onto the adhesive layer 614. The adhesive layer 614 may include glue, which facilitates attaching the carrier 701 to the second redistribution structure 112. The carrier 701 and the release film 702 include similar or the same materials as the carrier 601 and the release film 602, respectively, as described and illustrated with reference to FIG. 6A, and have a similar or the same dimension as the carrier 601 and the release film 602, respectively.

Referring to FIG. 6M, after the new carrier 701 with the release film 702 is bonded, the old carrier 601 and release film 602 are removed by, for example, a laser de-bonding process, exposing the buffer layer 603. The buffer layer 603 is then removed, exposing the first redistribution structure 111. Subsequently, referring to FIG. 6N, electrical conductors 126 are formed on the second surface 111s′ of the first redistribution structure 111 by a pre-soldering process.

Referring to FIG. 6O, a packaged device 130 is provided. The packaged device 130 includes one or more third semiconductor devices 13 sealed in an encapsulating layer 135, electrical conductors 146, and a redistribution structure 132 between the encapsulating layer 135 and the electrical conductors 146 for electric connection of the semiconductor devices 13 through the electrical conductors 146 to another semiconductor device. The electrical conductors 126 on the second surface 111s′ of the first redistribution structure 111 and the electrical conductors 146 of the packaged device 130 are jointed together by a reflowing process, resulting in electrical conductors 136, as illustrated in FIG. 6P. Referring to FIG. 6P, an underfill 137 is then applied between the first redistribution structure 111 and the packaged device 130. The underfill 137 provides protection of the third semiconductor devices 13 from moisture, ionic contaminants, radiation, and hostile operating environments with thermal, mechanical, shock, and vibration stresses.

Subsequently, referring to FIG. 6Q, the carrier 701 is removed by, for example, a laser de-bonding process, with the help of the release film 702. The adhesive layer 614 is then removed, exposing the electrical conductors 116 and the second semiconductor device 12 on the surface 112s of the second redistribution structure 112. Next, a singulation process is performed to saw the wafer into individual device units, each being similar to or the same as the semiconductor device package 10 as described and illustrated with reference to FIG. 1A.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A semiconductor device package, comprising:
a semiconductor device in an encapsulating layer;
an electrical conductor for electrical connection of the semiconductor device to an external device; and
a redistribution structure for electrical connection between the semiconductor device and the electrical conductor, the redistribution structure including:
dielectric layers stacked on each other in a direction extending between the encapsulating layer and the electrical conductor,
wherein at least one of the dielectric layers disposed adjacent to the electrical conductor has a larger size in the direction than at least one of the dielectric layers disposed adjacent to the encapsulating layer.

2. The semiconductor device package of claim 1, wherein the dielectric layer most adjacent to the electrical conductor has a larger size in the direction than the dielectric layer second most adjacent to the electrical conductor.

3. The semiconductor device package of claim 1, wherein the dielectric layer most adjacent to the electrical conductor has a same size in the direction as the dielectric layer second most adjacent to the electrical conductor.

4. The semiconductor device package of claim 1, wherein the dielectric layer most adjacent to the electrical conductor includes a first pattern under the electrical conductor, and wherein the redistribution structure includes circuit layers each corresponding to a respective one of the dielectric layers.

5. The semiconductor device package of claim 4 further comprising:
conductive regions, disposed in the dielectric layer most adjacent to the electrical conductor according to the first pattern, the conductive regions electrically connecting the circuit layer corresponding to the dielectric layer most adjacent to the electrical conductor and the circuit layer corresponding to the dielectric layer second most adjacent to the electrical conductor.

6. The semiconductor device package of claim 5, wherein the conductive regions include a first conductive region and a second conductive region spaced apart from the first conductive region by a dielectric region in the dielectric layer most adjacent to the electrical conductor.

7. The semiconductor device package of claim 5, wherein the circuit layer corresponding to the dielectric layer second most adjacent to the electrical conductor includes a pad region for electrical connection to the electrical conductor, and incudes a conductive portion connected to the pad region and extending therefrom.

8. The semiconductor device package of claim 4 further comprising:
a conductive region, disposed in the dielectric layer most adjacent to the electrical conductor according to the first pattern, the conductive region electrically connecting the circuit layer corresponding to the dielectric layer most adjacent to the electrical conductor and the circuit layer corresponding to the dielectric layer second most adjacent to the electrical conductor; and
a first dielectric region, disposed in the dielectric layer most adjacent to the electrical conductor under the electrical conductor according to the first pattern, and surrounded by the conductive region.

9. The semiconductor device package of claim 8, wherein the circuit layer corresponding to the dielectric layer second most adjacent to the electrical conductor includes a conductive portion connected to the projected region and extending therefrom.

10. The semiconductor device package of claim 8, wherein the circuit layer corresponding to the dielectric layer second most adjacent to the electrical conductor includes a second pattern under the electrical conductor, further comprising:
a second dielectric region, disposed in the circuit layer corresponding to the dielectric layer second most adjacent to the electrical conductor according to the second pattern, the second dielectric region connecting the first dielectric region and the dielectric layer second most adjacent to the electrical conductor.

11. The semiconductor device package of claim 11, wherein the first dielectric region is larger than the second dielectric region in area.

12. A semiconductor device package, comprising:
a semiconductor device in an encapsulating layer;
an electrical conductor for electrical connection of the semiconductor device to an external device;
a redistribution structure for electrical connection between the semiconductor device and the electrical conductor, the redistribution structure including:
dielectric layers stacked on each other in a direction extending between the encapsulating layer and the electrical conductor, wherein the dielectric layer most adjacent to the electrical conductor includes a first pattern under the electrical conductor; and
circuit layers each corresponding to a respective one of the dielectric layers, wherein the circuit layer corresponding to the dielectric layer second most adjacent to the electrical conductor includes a pad region for electrical connection to the electrical conductor, and incudes a conductive portion connected to the pad region and extending therefrom; and
at least one conductive region, disposed in the dielectric layer most adjacent to the electrical conductor according to the first pattern, the at least one conductive region electrically connecting the circuit layer corresponding to the dielectric layer most adjacent to the electrical conductor and the circuit layer corresponding to the dielectric layer second most adjacent to the electrical conductor.

13. The semiconductor device package of claim 12, wherein the alt least one conductive region include a first conductive region and a second conductive region spaced apart from the first conductive region by a dielectric region in the dielectric layer most adjacent to the electrical conductor.

14. The semiconductor device package of claim 12, wherein the dielectric layer most adjacent to the electrical conductor has a larger size in the direction than the dielectric layer second most adjacent to the electrical conductor.

15. The semiconductor device package of claim 12, wherein the dielectric layer most adjacent to the electrical conductor has a same size in the direction as the dielectric layer second most adjacent to the electrical conductor.

16. The semiconductor device package of claim 12 further comprising:
a first dielectric region, disposed in the dielectric layer most adjacent to the electrical conductor under the electrical conductor according to the first pattern, and surrounded by the at least one conductive region.

17. The semiconductor device package of claim 16, wherein the circuit layer corresponding to the dielectric layer second most adjacent to the electrical conductor includes a second pattern under the electrical conductor, further comprising:
a second dielectric region, disposed in the circuit layer corresponding to the dielectric layer second most adjacent to the electrical conductor according to the second pattern, the second dielectric region connecting the first dielectric region and the dielectric layer second most adjacent to the electrical conductor.

18. The semiconductor device package of claim 17, wherein the first dielectric region is larger than the second dielectric region in area.

19. The semiconductor device package of claim 12, wherein the dielectric layer most adjacent to the electrical conductor has a larger size in the direction than the dielectric layer second most adjacent to the electrical conductor.

20. The semiconductor device package of claim 12, wherein the dielectric layer most adjacent to the electrical conductor has a same size in the direction as the dielectric layer second most adjacent to the electrical conductor.
